(19) United States
(12) Patent Application Publication
(10) Pub. No.: US 2022/0285656 A1
(43) Pub. Date: Sep. 8, 2022

(54) DISPLAY DEVICE AND METHOD OF MANUFACTURING THE SAME

(71) Applicant: SAMSUNG DISPLAY CO., LTD., YONGIN-SI (KR)

(72) Inventors: YOUNGKI CHAI, Hwaseong-si (KR); DONGJO KIM, Suwon-si (KR); YOUNGJI KIM, Hwaseong-si (KR); SEONGGEUN WON, Hwaseong-si (KR); DANBI CHOI, Seongnam-si (KR); YOUNG SEO CHOI, Yongin-si (KR); SOUKJUNE HWANG, Seoul (KR)

(21) Appl. No.: 17/517,887

(22) Filed: Nov. 3, 2021

(30) Foreign Application Priority Data
Mar. 5, 2021 (KR) 10-2021-0029646

(51) Int. Cl. H01L 51/52; H01L 27/32; H01L 51/56

(52) U.S. Cl. CPC H01L 51/5284; H01L 51/5293; H01L 27/3234; H01L 51/5237; H01L 51/56; H01L 27/3218

(57) ABSTRACT

A display device with increased light transmittance to a functional module includes a substrate, a light blocking layer, an insulating layer, emission elements, and a polarization member. The substrate includes a first display region including a first pixel region and a transmission region, and a second display region surrounding at least a portion of the first display region and including a second pixel region. The light blocking layer is disposed in both display regions on the substrate and includes a first opening overlapping the transmission region. The insulating layer covers the light blocking layer on the substrate. The emission elements are disposed in the first and second pixel regions on the insulating layer. The polarization member is disposed on the emission elements and includes a second opening overlapping die first opening. An area of the second opening is greater than or equal to an area of the first opening.

### CROSS-REFERENCE TO RELATED APPLICATION

This U.S. nonprovisional application claims priority under 35 U.S.C. § 119 to Korean Patent Application No. 10-2021-0029646, filed on Mar. 5, 2021, the entire disclosure of which is incorporated by reference herein in its entirety.

### TECHNICAL FIELD

Embodiments of the present disclosure relate generally to a display device. More particularly, embodiments relate to a display device including a polarization member and a method of manufacturing the display device.

### DISCUSSION OF THE RELATED ART

Display devices are used to display images, video, applications, and interfaces to users. There are several types of display devices, including organic light emitting displays (“OLED”), liquid crystal displays (“LCD”), and others.

Display devices may include various functional modules that may be used together with the display device. For example, a user may take a picture, a video, and the like using a camera module disposed inside the display device. Such a camera module may be disposed in a non-display region of the display device in order to secure an area dedicated for the camera module.

However, in some cases, using a non-display region may reduce the available display area in a display device. Accordingly, various studies are being conducted to dispose the functional modules in the display region of the display device.

### SUMMARY

Embodiments of the present disclosure provide a display device including a polarization member.

Embodiments of the present disclosure provide a method of manufacturing the display device.

A display device according to an embodiment of the present disclosure includes a substrate, a light blocking layer, an insulating layer, emission elements, and a polarization member. The substrate includes a first display region including a first pixel region and a transmission region, and a second display region surrounding at least a portion of the first display region and including a second pixel region. The light blocking layer is disposed on the substrate in the first and second display regions and includes a first opening overlapping the transmission region in a vertical direction, where the vertical direction is a direction that is normal to a surface of the substrate. The insulating layer covers the light blocking layer on the substrate. The emission elements are disposed on the insulating layer in the first and second pixel regions. The polarization member is disposed on the emission elements and includes a second opening overlapping the first opening. An area of the second opening is greater than or equal to an area of the first opening.

In an embodiment of the present disclosure, the display device may further include a functional module disposed under the substrate corresponding to the first display region.

In an embodiment of the present disclosure, the functional module may include a camera module, a face recognition sensor module, a pupil recognition sensor, an acceleration sensor module, a proximity sensor module, an infrared sensor module, and/or an illuminance sensor module.

In an embodiment of the present disclosure, the polarization member may include a phase delay layer disposed on the emission elements, a support layer disposed on the phase delay layer, and a polarization layer disposed on the support layer.

In an embodiment of the present disclosure, the support layer may include tri acetyl cellulose (“TAC”). The polarization layer may include polyvinyl alcohol (“PVA”),

In an embodiment of the present disclosure, the second opening may be defined as a removed portion of the polarization layer, where the removed portion is a portion that overlaps the first opening.

In an embodiment of the present disclosure, the first display region may further include a peripheral region surrounding the first pixel region and the transmission region.

In an embodiment of the present disclosure, the light blocking layer may overlap the first pixel region, the second pixel region, and the peripheral region. The light blocking layer may not overlap the transmission region.

In an embodiment of the present disclosure, the display device may further include an encapsulation layer disposed between the emission elements and the polarization member, and a window member disposed on the polarization member.

A method of manufacturing a display device according to an embodiment of the present disclosure is provided herein. According to the method, a substrate is formed that includes a first display region including a first pixel region and a transmission region, and a second display region surrounding at least a portion of the first display region and including a second pixel region. A light blocking layer is formed in the first and second display regions on the substrate. A first opening is formed by removing a portion of the light blocking layer overlapping the transmission region. An insulating layer covering the light blocking layer is formed on the substrate. Emission elements are formed on the insulating layer in the first and second pixel regions. A polarization member is formed on the emission elements. A second opening is formed by irradiating a laser to a lower portion of the substrate overlapping the transmission region in order to remove a portion of the polarization member overlapping the first opening.

In an embodiment of the present disclosure, the polarization member may include a phase delay layer formed on the emission elements, a support layer formed on the phase delay layer, and a polarization layer formed on the support layer.

In an embodiment of the present disclosure, the support layer may include tri acetyl cellulose (“TAC”). The polarization layer may include polyvinyl alcohol (“PVA”).

In an embodiment of the present disclosure, the second opening may be defined as a portion from which the polarization layer overlapping the first opening is removed.

in an embodiment of the present disclosure, in the forming of the second opening, a portion of the polarization layer overlapping the first opening may be scanned in a first direction using the laser, The second opening may be formed in a second direction perpendicular to the first direction.

In an embodimentof the present disclosure, an area of the second opening may be greater than or equal to an area of the first opening.

In an embodiment of the present disclosure, the light blocking layer may overlap the first pixel region, the second pixel region, and the peripheral region. The light blocking layer may not overlap the transmission region.

In an embodiment of the present disclosure, after forming the second opening, the second opening may be cleaned with a neutral solution.

In an embodiment of the present disclosure, the neutral solution may have a temperature of about 5° C. to about 90° C.

In an embodiment of the present disclosure, the laser may include a continuous wave laser or a pulsed laser.

In an embodiment of the present disclosure, a wavelength of the laser may be about 340 nm to about 1000 nm. An intensity of the laser may be about 0.5 W to about 20 W

In a display device according to an embodiment of the present disclosure, the display device rnay include a substrate including a first display region including a first pixel region and a transmission region, a light blocking layer including a first opening overlapping the transmission region, and a polarization member including a second opening overlapping the first opening. An area of the second opening may be greater than or equal to an area of the first opening. Accordingly, a transmittance of light through the transmission region may be increased.

In the method of manufacturing a display device according to an embodiment of the present disclosure, a laser may be irradiated to a lower portion of the display device overlapping the transmission region. Accordingly, a portion of the polarization layer overlapping the transmission region may be entirely removed, and a transmittance of light through the transmission region may be increased.

### BRIEF DESCRIPTION OF THE DRAWINGS

The above and other aspects and features of the present disclosure will be more clearly understood from the tbilowing detailed description of embodiments thereof, taken in conjunction with the accompanying drawings, in which:

FIG. 1. is a plan view that illustrates a display device according to an embodiment;

FIG. 2 is a cross-sectional view that illustrates a first display region and a second display region of the display device of FIG. 1;

FIG. 3 is a plan view that illustrates a first display region of the display device of FIG. 1;

FIG. 4 is a plan view that illustrates a second display region of the display device of FIG, 1;

FIG. 5 is a cross-sectional view taken along line I-I′ of FIG. 3; and

FIGS. 6, 7, 8, 9, and 10 are diagrams that illustrate a method of manufacturing a display device according to an embodiment.

### DETAILED DESCRIPTION OF THE EMBODIMENTS

Hereinafter, embodiments of the present disclosure will be explained in detail with reference to the accompanying drawings. Like reference numerals may refer to like components, and to the extent that a description of an element has been omitted, it may be understood that the element is at least similar to corresponding elements that are described elsewhere in the specification.

In some comparative examples of display devices, there may be a first opening of a light blocking layer positioned directly above emission elements, and a second opening of a polarization layer positioned above the light blocking layer. In the comparative examples, the second opening may be smaller than the first opening, causing a decreased transmittance of light However, in a display device according to the present disclosure, the second opening of the polarization layer may be larger than the first opening of the light blocking layer, resulting increased transmittance of light. The increased transmittance of light may provide increased performance of a functional module disposed underneath the openings, such as a camera module, and may result increased facial recognition, imaging, and general performance of the functional module.

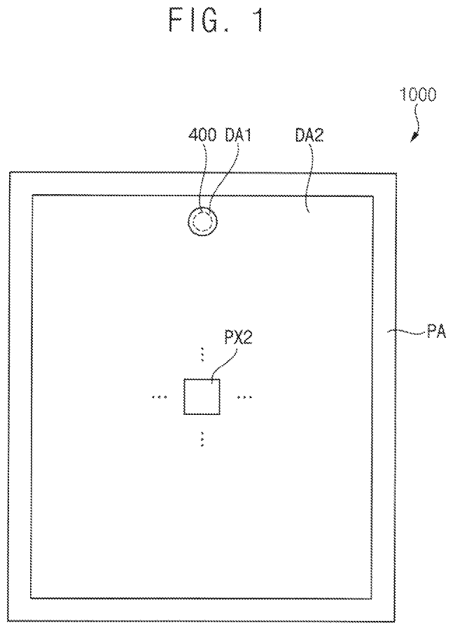

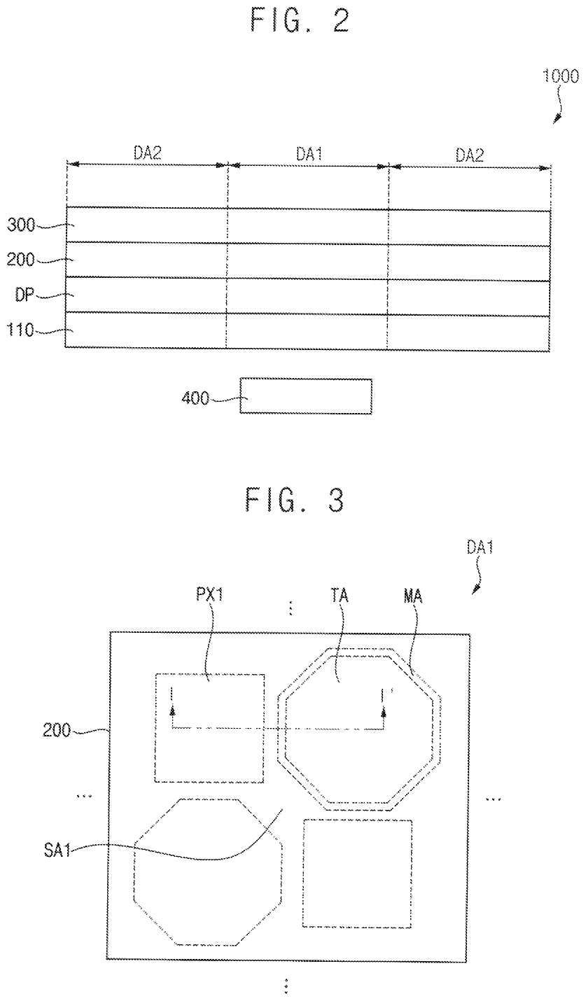

FIG. 1 is a plan view that illustrates a display device according to an embodiment. FIG. 2 is a cross-sectional view that illustrates a first display region and a second display region of the display device of FIG. 1.

Referring to FIGS. 1 and 2, the display device 1000 may include a substrate 110, a display portion DP, a polarization member 200, a window member 300, and a functional module 400.

The display device 1000 may include a first display region DA1, a second display region DA2, and a non-display region PA. Each of the first display region DA1 and the second display region DA2 may display an image. The non-display region PA may be an area in which an image is not displayed. The first display region DA1 may include a transmission region through which an external light transmits. For example, the transmission region may include material(s) with a relatively high transmittance of visible light. As the first display region DA1 includes the transmission region, a transmittance of the first display region DA1 may be higher than a transmittance of the second display region DA2. For example, the transmittance of the second display region DA2 may be lower than the transmittance of the first display region DA1. For example, the first display region DA1 may transmit external light that is incident on the first display region DA1 while also displaying an image.

The first display region DA1 may include a plurality of first pixel regions PX1. The second display region DA2 may include a plurality of second pixel regions PX2. A plurality of pixels which can display an image may be disposed in each of the first and second pixel regions PX1 and PX2. Each of the pixels may emit light of a specific color (e.g., red, green, or blue).

A plurality of drivers may be disposed in the non-display region PA. For example the drivers may include a gate driver, a light emission control driver, a data driver, and the like. The drivers may provide a gate signal, a data signal, an emission control signal, and the like to the pixels.

The frst display region DA1 and the second display region DA2 may be positioned adjacent to each other. In an embodiment of the present inventive concepts, the second display region DA2 may surround at least a portion of the first display region DA1. For example, the first display region DA1 may be positioned within the display device 1000 while being spaced apart fron an edge of the display device 1000 in a plan view. The second display region DA2 may surround an entire first display region DA1. For example, the second display region DA2 may surround the first display region DA1 in a plan view.

The first display region DA1 may have a circular planar shape. However, the shape of the first display region DA1 is not necessarily limited thereto, and the first display region DA1 may have various shapes, such as planar polygonal shapes, freeform shapes, and the like.

The display portion DP may be disposed on the substrate 110. The display unit DP may include the pixels for displaying the image.

The functional module 400 may be disposed below the display device 1000 in a region which corresponds to the first display region DA1. As used herein, when one region corresponds to another, this may describe a positional relationship in which the regions at least partially overlap each other in a vertical direction, such as a direction normal to the surface of the display device 1000. The functional module 400 may receive external light that is transmitted through the first display region DA1. In an embodiment of the present inventive concepts, the functional module 400 may include a camera module for photographing (or recognizing) an image of an object located in front of the display device 1000, a face recognition sensor module for detecting a user's face, a pupil recognition sensor module for detecting a user's pupil, an acceleration sensor module and a geomagnetic sensor module for determining a movement of the display device 1000, a proximity sensor module and an infrared sensor module for detecting whether a front of the display device 1000 is in proximity, and an illuminance sensor.module for measuring a degree of external brightness.

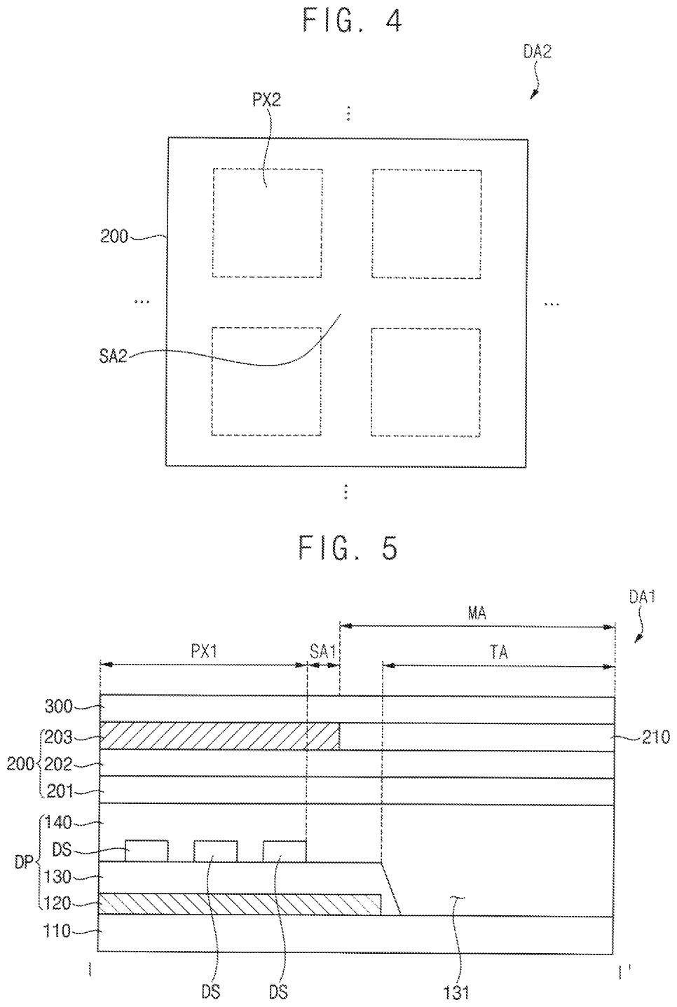

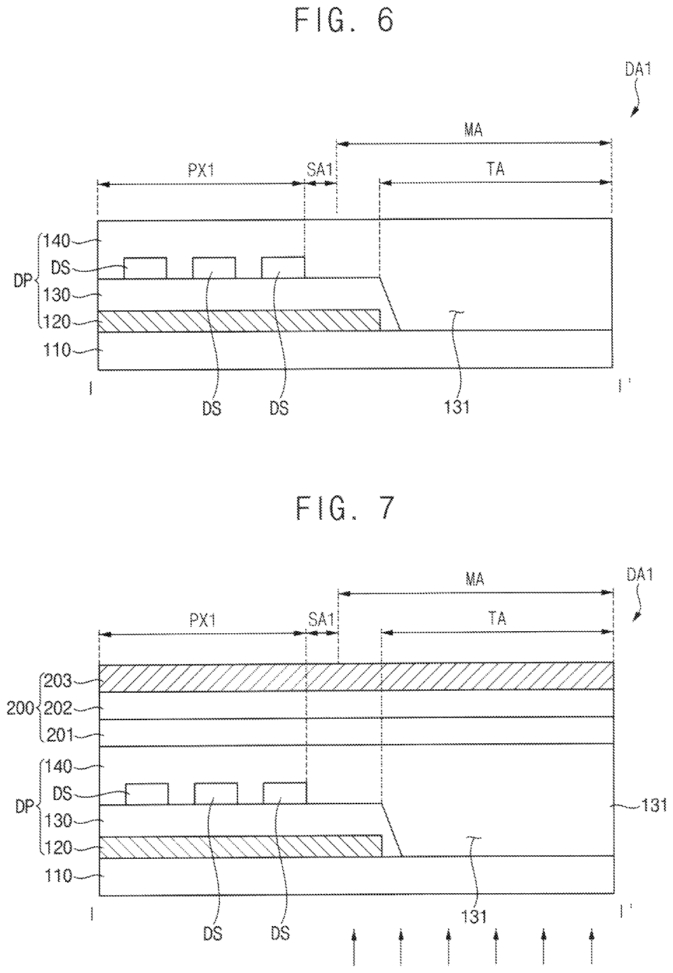

FIG. 3 is a plan view that illustrates a first display region of the display device of FIG. 1. FIG. 4 is a plan view that illustrates a second display region of the display device of FIG. 1.

Referring to FIGS. 3 and 4, the first display region DA1 may include the first pixel region PX1, a transmission region TA, and a first peripheral region SA1. The second display region DA2 may include the second pixel region PX2 and a second peripheral region SA2.

As described with reference to FIG. 1, each of the first and second pixel regions PX1 and PX2 may be an area in which the pixels are disposed and in which a light generated from each of the pixels is emitted. Each of the first and second pixel regions PX1 and PX2 may include a plurality of sub-pixel regions configured to emit light of different colors. For example, the sub-pixel regions may include a red sub-pixel region emitting red light, a green sub-pixel region emitting green light, and a blue sub-pixel region emitting blue light. For example, the sub-pixel regions may be arranged in a stripe manner or in a PenTile™ manner

The transmission region TA may be a region through which external light incident on the display device 1000 is transmitted. As the first display region DA1 includes the transmission region TA through which the external light transmits, the functional module 400 disposed under the display device 1000 in a region which corresponds to the first display region DA1 may detect or recognize an object or a user located in front of the display device 1000 through the transmission region TA.

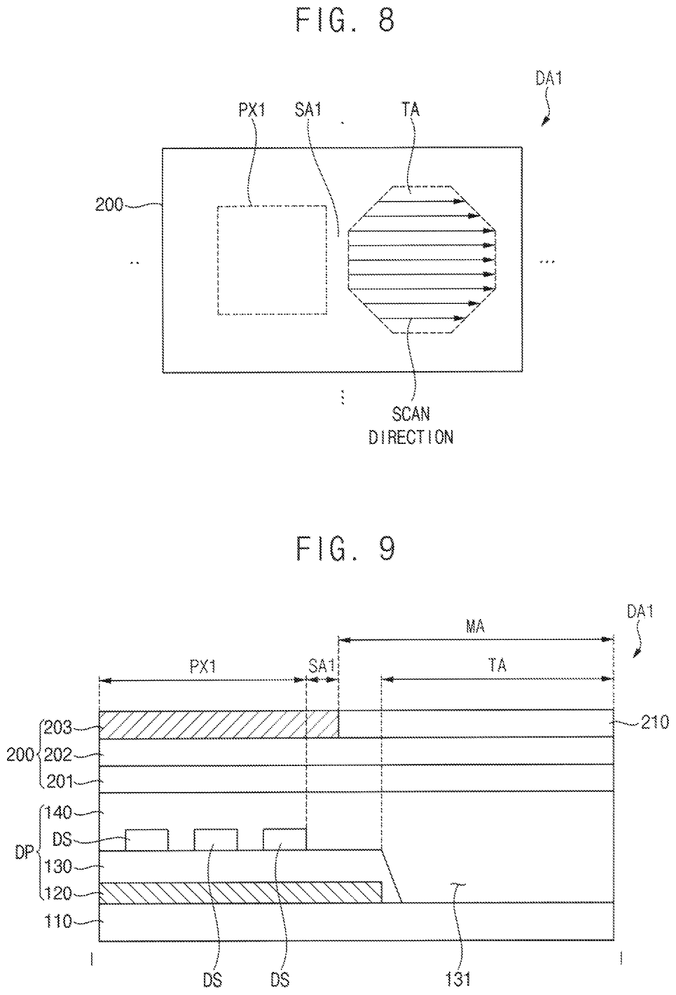

As will be described later, in order for the functional module 400 to detect or recognize an object or a user located in front of the display device 1000 through the transmission region TA, a portion of the polarization member 200 that overlaps the transmission region TA may be removed by irradiating a laser. In this case, the portion of the polarization member 200 that overlaps the transmission region TA may be removed to form a processing region MA. For example, the processing region MA may be defined as an area in which the portion of the polarization member 200 that overlaps the transmission region TA is removed. The processing region MA may overlap the second opening 210 shown in FIG. 5. For example, in a plan view, an area of the processing region MA may be the same as an area of the second opening 210 shown in FIG. 5.

The processing region MA may overlap the transmission region TA. For example, the processing region MA may overlap the transmission region TA in a vertical direction. The processing region MA may transmit the external light in a manner similar to the transmission region TA. In an embodiment of the present inventive concepts, in a plan view, an area of the processing region MA may be the same as an area of the transmission region TA. In an embodiment of the present inventive concepts, the area of the processing region MA may be larger than the area of the transmission region TA. For example, the processing region MA may have an area that is about 1.1 times the size of the area of the transmission region TA. Accordingly, a transmittance of light through the transmission region TA may increase.

The first peripheral region SA1 may surround the first pixel region PX1 and the transmission region TA. The second peripheral region SA2 may surround the second pixel region PX2. The first and second peripheral regions SA1 and SA2 might not emit light and or transmit external light.

In FIG. 3, the first display region DA1 may include two transmission regions TA and two first pixel regions PX1, but the embodiments of the present inventive concepts are not necessarily limited thereto. For example, the first display region DA1 may include at least one transmission region TA and at least one first pixel region PX1.

In addition, in FIG. 4. the second display region D2 includes four second pixel regions PX2, but the embodiments of the present inventive concepts are not necessarily limited thereto. For example, the second display region DA2 may include at least one second pixel region PX2.

Hereinafter, a display device including an organic light emitting diode (“OLED”) as an emission element will be described for convenience, but the embodiments of the present inventive concepts are not necessarily limited thereto, the present inventive concepts may be applied to various types of display devices, such as a diode display (“LED”) device, an electrophoretic display device, and the like.

FIG. 5 is a cross-sectional view taken along line I-I′ of FIG. 3. FIG. 5 is a cross-sectional view that illustrates the first display region DA1 of the display device 1000 of FIG. 1.

Referring to FIGS. 3, 4, and 5, the display device 1000 may include the substrate 110, the display portion DP, the polarization member 200, and the window member 300. The display portion DP may include a light blocking layer 120, air insulating layer 130, emission elements DS, and an encapsulation layer 140.

The substrate 110 may include the first display region DA1 and the second display region DA2. The substrate 110 may include a transparent material and/or an opaque material. For example, the substrate 110 may include glass, quartz, plastic, and the like. In addition, a buffer layer may be disposed on the substrate 110, The buffer layer may prevent diffusion of metal atoms or impurities from the substrate 110 to other components, such as to a thin film transistor,

The light blocking layer 120 may be disposed in the first display region DA1 on the substrate 110. In addition, the light blocking layer 120 may be disposed on the second display region DA2 on the substrate 110. The light blocking layer 120 may serve to maintain a constant voltage characteristic of the thin film transistor. For example, the light blocking layer 120 may include a conductive material such as titanium (Ti), molybdenum (Mo), copper (Cu), and the like. In an embodiment of the present inventive concepts, the light blocking layer 120 may not overlap the transmission region TA. For example, the light blocking layer 120 may be disposed in the first pixel region PX1 and the first peripheral region SA1.

In an embodiment of the present inventive concepts, the light blocking layer 120 in the first display region DA1 raatay include a first opening 131 which overlaps the transmission region TA.

The thin film transistor may be disposed on the substrate 110 and the light blocking layer 120. The thin film transistor may be connected to the emission elements DS disposed on the substrate 110.

The insulating layer 130 may be disposed on the substrate 110 and the light blocking layer 120. The insulating layer 130 may at least partially cover the light blocking layer 120. In an embodiment of the present inventive concepts, the insulating layer 130 may cover upper and lateral sides of the light blocking layer 120. The insulating layer 130 may be entirely disposed in the first display region DA1, the second display region DA2, and the non-display region PA shown in FIG. 1. The insulating layer 130 may include at least one inorganic insulating layer and at least one organic insulating layer. For example, the inorganic insulating layer may include a silicon compound, silicon nitride, silicon oxide, and the like. The organic insulating layer may include a polyimide-based resin, a polyamide-based resin, siloxane-based resin, acryl-based resin, epoxy-based resin, and the like.

The plurality of emission elements DS may be disposed in the first pixel region PX1 on the insulating layer 130. In addition, the plurality of emission elements DS may be disposed in the second pixel region PX2 on the insulating layer 130. The plurality of emission elements DS may be spaced apart from each other. Light generated by the plurality of emission elements DS may pass through the encapsulation layer 140, the polarization member 200, and the window member 300 to be emitted to an outside of the display device 1000.

The plurality of emission elements DS may emit light of different colors. In an embodiment of the present inventive concepts, all of the plurality of emission elements DS may emit light of the same color, However, embodiments of the present inventive concepts are not necessarily limited thereto, and the method in which the plurality of emission elements DS emit light is not necessarily limited thereto.

The encapsulation layer 140 may be disposed on the insulating layer 130 and the emission elements DS. The encapsulation layer 140 may be disposed in the first display region DA1, the second display region DA2, and the non-display region PA shown in FIG. 1. The encapsulation layer 140 may include at least one inorganic layer and at least one organic layer. The encapsulation layer 140 may be disposed on the emission elements DS to prevent external impurities from flowing into the emission elements DS and to protect the emission elements DS from external impact. In addition, a portion of the encapsulation layer 140 that overlaps the transmission region TA may fill the first opening 131.

For example, the organic layer may include a cured polymer such as polyacrylate (PAR). For example, the inorganic layer may include silicon oxide (SiOx), silicon nitride (SiNx). silicon carbide (SiCx), aluminum oxide (AlOx) tantalum oxide (TaOx), hafnium oxide (HfOx), zirconium oxide (ZrOx), Titanium oxide (TiOx) and the like.

The polarization member 200 may be disposed on the encapsulation layer 140. in an embodiment of the present inventive concepts, the polarization member 200 ma include a phase delay layer 201, a support layer 202, and a polarization layer 203. The polarization member 200 may block an external light incident from the outside.

Specifically, the phase delay layer 201 may be disposed on the encapsulation layer 140. The phase delay layer 201 may delay the phase of the incident light by 1/2λ or delay the phase of the incident light by 1/4λ to change a linear polarization to a circular polarization or the circular polarization to the linear polarization. For example, the phase delay layer 201 may include at least one of a 1/2λ phase delay, layer and a 1/4λ phase delay layer.

The support layer 202 may be disposed on the phase delay layer 201. The support layer 202 may support the polarization layer 203 and supplement a mechanical strength of the polarization layer 203. In addition, the support layer 202 may prevent the polarization layer 203 from being deformed as a result of a change in temperature or a change in humidity.

The support layer 202 may be disposed on an upper surface or a lower surface of the polarization layer 203, or may be disposed on both the upper surface and the lower surface of the polarization layer 203. For example, the support layer 202 may include tri acetyl cellulose (“TAC”).

The polarization layer 203 may be disposed on the support layer 202. The polarization layer 203 may polarize light incident from a light source. For example, the polarization layer 203 may polarize incident light into light that propagates in a same direction as a polarization axis. The polarization layer 203 may be formed by including a polarizer and/or a dichroic dye in a polyvinyl alcohol (“PVA”) film. The dichroic dye may include iodine molecules and/or dye molecules.

In order to attach the phase delay layer 201, the support layer 202 and the polarization layer 203 to each other, an adhesive layer may be disposed between the phase delay layer 201 and the support layer 202, and between the support layer 202 and the polarization layer 203. For example, the adhesive layer may include a material that is substantially transparent to visible light.

In order for external light incident on the transmission region TA of the first display region DA1 to be transmitted, a portion of the polarization layer 203 that overlaps the transmission region TA must be removed. In addition, a transmittance of light through the transmission region TA may be increased only when a portion of the polarization layer 203 that overlaps the transmission region TA is completely removed.

In an embodiment of the present inventive concepts, the polarization member 200 may include the second opening 210 which overlaps the first opening 131. The second opening 210 may he a portion from which the polarization layer 203 that overlaps the first opening 131 is removed. In addition, the second opening 210 may overlap the processing region MA. For example, as described above, in a plan view, an area of the second opening 210 may be the same as an area of the processing region MA.

In an embodiment of the present inventive concepts, iri a plan view, the area of the second opening 210 may be the same as the area of the first opening 131. In an embodiment of the present inventive concepts, in a plan view, the area of the second opening 210 may be larger than the area of the first opening 131. For example, the second opening 210 may have an area that is about 1.1 times the size of the area of the first opening 131. Accordingly, a transmittance of light through the transmission region TA may be increased.

In an embodiment of the present inventive concepts, the second opening 210 may be formed using a laser. For example, a wavelength of the laser may be about 340 nm to about 1000 nm, and an intensity of the laser may be about 0.5 W to about 20 W. The laser may include a continuous wave laser or a pulsed laser. For example, the pulse laser may include a pulse laser of femtosecond or longer.

In an embodiment of the present inventive concepts, the second opening 210 may be formed using a chemical material. For example, the second opening 210 may be formed by treating the polarization layer 203 with a neutral solution. For example, a temperature of the neutral solution may be about 5° C. to about 90° C.

In an embodiment of the present inventive concepts, the second opening 210 may be formed using the laser and the chemical material. For example, after irradiating the laser to the polarization layer 203, the second opening 210 may be formed by treating the area irradiated with the laser with the neutral solution.

In an embodiment of the present inventive concepts, a portion of the polarization layer 203 that overlaps the transmission region TA may be entirely removed by irradiating the laser onto a lower portion of the display device 1000 that overlaps the transmission region TA. For example, the second opening 210 may be formed by irradiating the laser to the lower portion of the display device 1000 that overlaps the transmission region TA to remove the portion of the polarization layer 203 that overlaps the transmission region TA.

In a comparative example of a display device, an area of a second opening of a polarization member that overlaps a transmission region is smaller than an area of a first opening of a light blocking layer that overlaps the transmission region. Accordingly, a transmittance of light through the transmittance area is relatively small.

In a display device 1000 according to an embodiment of the present inventive concepts, the display device 1000 may include the substrate 110 including the first display region DA1 including the first pixel region PX1 and the transmission region TA, the light blocking layer 120 including the first opening 131 which overlaps the transmission region TA, and the polarization layer 203 including the second opening 210 which overlaps the first opening 131. The area of the second opening 210 may be greater than or equal to the area of the first opening 131. Accordingly, a transmittance of light through the transmission region TA may be increased.

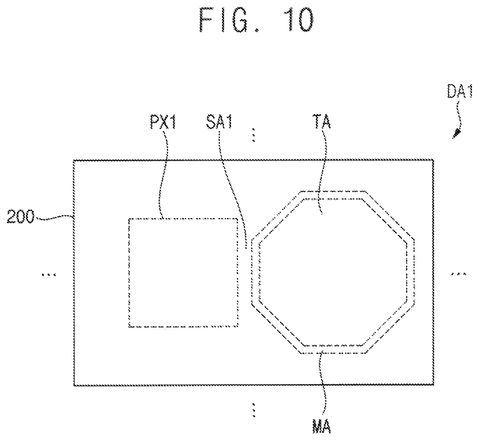

FIGS. 6, 7, 8, 9, and 10 are diagrams that illustrate a method of manufacturing a display device according to an embodiment. For example, FIG. 8 is a top plan view of the display device 1000 of FIG. 7. FIG. 10 is a top plan view of the display, device 1000 of FIG. 9.

Referring to FIG. 6, the substrate 110 which includes a transparent material or an opaque material may be provided. For example, the substrate 110 may include glass, quartz, plastic, and the like. In addition, the buffer layer may be formed on the substrate 110. For example, the buffer layer may include an inorganic material such as oxide or nitride. The light blocking layer 120 may be formed in the first and second display regions PX1 and PX2 on the substrate 110 (see FIGS. 1 and 2). For example, the light blocking layer 120 may include a conductive material such as Ti, Mo, Cu, and the like. In an embodiment of the present inventive concepts, the first opening 130 may be formed by removing a portion of the light blocking layer 120 that overlaps the transmission region TA. Accordingly, the light blocking layer 120 may overlap the first pixel region PX1, the second pixel region PX2, and the first peripheral region SA1, but may not overlap the transmission region TA.

The thin film transistor may be disposed on the substrate 110 and the light blocking layer 120. The thin film transistor may be connected to the emission elements DS disposed on the substrate 110.

The insulating layer 130 may be formed on the sUbstrate 110 and the light blocking layer 120. The insulating layer 130 may be formed in the first display region DA1, the second display region DA2, and the non-display region PA shown in FIG. 1. The insulating layer 130 may include at least one inorganic insulating layer and at least one organic insulating layer. For example, the inorganic insulating layer may include silicon oxide or silicon nitride. The organic insulating layer may include a polyimide-based resin, a polyamide-based resin, and the like.

The plurality of emission elements DS may be formed in each of the first and second pixel regions PX1 and PX2 on the insulating layer 130 (see FIGS. 1 and 2). The plurality of emission elements DS may be spaced apart from each other. In addition, the plurality of emission elements DS may o er lap the light blocking layer 120. The encapsulation layer 140 may be formed on the insulating layer 130 and the emission elements DS. In addition, a portion of the encapsulation layer 140 that overlaps the transmission region TA may fill the first opening 131. The encapsulation layer 140 may be formed in the first display region DA1, the second display region DA2, and the non-display region PA shown in FIG. 1. The encapsulation layer 140 may include at least one inorganic layer and at least one organic layer. For example, the organic layer may include a cured polymer such as polyactylate. The inorganic layer may include silicon oxide or silicon nitride.

Referring to FIGS. 7 and 8, the polarization member 200 may be formed on the encapsulation layer 140. The polarization member 200 may include the phase delay layer 201 formed on the encapsulation layer 140, the support layer 202 formed on the phase delay layer 201, and the polarization layer 203 formed on the support layer 202.

In an embodiment of the present inventive concepts, the laser may be irradiated onto the lower portion of the display device 1000 that overlaps the transmission region TA. The portion of the polarization member 200 that overlaps the transmission region TA may be removed by irradiating the laser onto the lower portion of the display device 1000 that overlaps the transmission region TA. For example, the portion of the polarization layer 203 that overlaps the transmission region TA may be removed by irradiating the laser to the lower portion of the display device 1000 that overlaps the transmission region TA.

In an embodiment of the present inventive concepts, a wavelength of the laser may be about 340 nm to about 1000 nm, and an intensity of the laser may be about 0.5 W to about 20 W. The laser may include a continuous wave laser or a pulsed laser.

In an embodiment of the present inventive concepts, the portion of the polarization layer 203 that overlaps the transmission region TA may be entirely removed by irradiating the laser onto the lower portion of the display device 1000 that overlaps the transmission region TA. In this case, the light blocking layer 120 serves as a mask, and a portion of the polarization layer 203 that overlaps the light blocking layer 120 might not be removed. However, when the laser scatters or diffracts due to the light blocking layer 120, a portion of the polarization layer 203 that overlaps the light blocking layer 120 may be removed.

In an embodiment of the present inventive concepts, a portion of the polarization layer 203 that overlaps the first opening 131 may be scanned in a first direction using the laser. In addition, the second opening 210 may be formed along a second direction which is orthogonal to the first direction.

Referring to FIGS. 9 and 10, in an embodiment of the present inventive concepts, the second opening 210 may be formed by irradiating the laser onto the lower portion of the display device 1000 that overlaps the transmission region TA to remove a portion of the polarization member 200 that overlaps the first opening 131. In this case, the second opening 210 may be defined as a portion from which the polarization layer 203 that overlaps the first opening 131 is removed.

In an embodiment of the present inventive concepts, after irradiating the laser onto the lower portion of the display device 1000 that overlaps the transmission region TA, an area in which the laser is irradiated may be treated with a neutral solution. For example, the second opening 210 of the polarization layer 203 may be cleaned with the neutral solution. A temperature of the neutral solution may be about 5° C. to about 90° C.

Accordingly, the display device 1000 shown in FIG. 1 may be manufactured.

In a comparative example, by irradiating a laser to an upper portion of a display device that overlaps the transmission region, a portion of a polarization layer that overlaps the transmission region is not entirely removed.

In the method of manufacturing the display device 1000 according to an embodiment of the present inventive concepts, the laser may be irradiated onto the lower portion of the display device 1000 that overlaps the transmission region TA. Accordingly, a portion of the polarization layer 203 that overlaps the transmission region TA may be entirely removed, and a transmittance of light through the transmission region TA may be increased.

The present inventive concepts may be applied to a display device and an electronic device including the same. For example, the present inventive concepts may be applied to high-resolution smartphones, mobile phones, smart pads, smart watches, tablet PCs, vehicle navigation systems, televisions, computer monitors, notebook computers, and the like.

The foregoing description is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is clamed is:

1. A display device comprising:
substrate including a first display region including a first pixel region and a transmission region, and a second display region surrounding at least a portion of the first display region and including a second pixel region;
a light blocking layer disposed on the substrate and in the first and second display regions, wherein the light blocking layer includes a first opening overlapping the transmission region in a vertical direction normal to a surface of the substrate;
an insulating layer covering the light blocking layer on the substrate;
emission elements disposed on the insulating layer in the first and second pixel regions; and
a polarization member disposed on the emission elements, wherein the polarization member includes a second opening overlapping the first opening in the vertical direction;
wherein an area of the second opening is greater than or equal to an area of the first opening.

2. The display device of claim 1. further comprising:
a functional module disposed under the substrate and corresponding to the first display region.

3. The display device of claim 2, wherein the functional module includes:
a camera module, a face recognition sensor module, a pupil recognition sensor, an acceleration sensor module, a proximity sensor module, an infrared sensor module, or a illuminance sensor module.

4. The display device of claim 1, wherein the polarization member includes:
a phase delay layer disposed on the emission elements;
a support layer disposed on the phase layer; and
a polarization layer disposed on the support layer.

5. The display device of claim 4, wherein the support layer includes tri acetyl cellulose (“TAC”), and
wherein the polarization layer includes polyvinyl alcohol (“PVA”).

6. The display device of claim 4, wherein the second opening is a removed portion of the polarization layer.

7. The display device of claim. 1. wherein the first display region further comprises:
a peripheral region surrounding the first pixel region and the transmission region.

8. The display device of claim 7, wherein the light blocking layer overlaps the first pixel region, the second pixel region, and the peripheral region, and
wherein the light blocking layer does not overlap the transmission region.

9. The display device of claim 1, further comprising:
an encapsulation layer disposed between the emission elements and the polarization member; and
a window member disposed on the polarization member.

10. A method of manufacturing a display device, the method comprising:
providing a substrate including a first display region including a first pixel region and a transmission region, and a second display region surrounding at least a portion of the first display region and including a second pixel region;
forming a light blocking layer in the first and second display regions on the substrate;
forming a first opening by removing a portion of the light blocking layer overlapping the transmission region;
forming an insulating layer covering the light blocking layer on the substrate;
forming emission elements in the first and second pixel regions on the insulating layer;
forming a polarization member on the emission elements; and
forming a second opening by irradiating a laser to a lower portion of the substrate overlapping the transmission region in order to remove a portion of the polarization member overlapping the first opening.

11. The method of claim 10, wherein the polarization member includes:
a phase delay layer formed on the emission elements;
a support layer formed on fhe phase delay layer; and
a polarization layer formed on the support layer.

12. The method of claim 11, wherein the support layer includes tri acetyl cellulose (“TAC”) and the polarization layer includes polyvinyl alcohol (“PVA”).

13. The method of claim 11, wherein the second opening is a removed portion of the polarization layer.

14. The method of claim 11, wherein the forming of the second opening includes:
scanning a portion of the polarization layer overlapping the first opening in a first direction using the laser, and
forming the second opening in a second direction that is perpendicular to the fist direction.

15. The method of claim 10, wherein an area of the second opening is greater than or equal to an area of the first opening.

16. The method of claim 10, wherein the light blocking layer overlaps the first pixel region, the second pixel region, and the peripheral region, and
wherein the light blocking layer does not overlap the transmission region.

17. The method of claim 10, further comprising:
cleaning the second opening with a neutral solution after forming the second opening.

18. The method of claim 17, wherein the neutral solution has a temperature of about 5° C. to about 90° C.

l9. The method of claim 10, wherein the laser includes a continuous wave laser or a pulsed laser.

20. The method of claim 10, wherein a wavelength of the laser is about 340 nm to about 1000 nm, and
wherein an intensity of the laser is about 0.5 W to about 20 W.
